(19) United States
(12) Patent Application Publication
(10) Pub. No.: US 2010/0204820 A1
(43) Pub. Date: Aug. 12, 2010

(54) APPARATUS AND METHOD FOR SUBSTRATE HANDLING

(76) Inventors: Moshe Finarov, Rehovot (IL); Beniamin Schulman, Rehovot (IL)

Correspondence Address: DANIEL J SWIRSKY, 55 REUVEN ST., BEIT SHEMESH, 99544, IL

(21) Appl. No.: 12/602,770

(22) PCT Filed: Jun. 5, 2008
(86) PCT No.: PCT/IL08/00779

§ 371 Date: Apr. 29, 2010

(30) Foreign Application Priority Data
Jun. 5, 2007 (IL) 183692

(51) Int. Cl. H01L 21/68

(52) U.S. Cl. 700/213

(57) ABSTRACT

A system for substrate handling proposed, comprising an optical local tilt detector, a plurality of arms each having vertically extended movable along vertical axis fingers to contact the edge of a substrate, wherein at least one of the arms has a linear actuator moveable arm and each of the fingers provided by z-axis miniature linear actuator; and a control unit connected to said tilt detector and said z-axis linear actuators enabling measuring and correcting of local tilt.

### FIELD OF THE INVENTION

The present invention relates generally to substrate handling systems and techniques, such as those used in semiconductor manufacturing and in particular to optical based processing such as metrology or inspection of semiconductor wafers.

### BACKGROUND

In most of techniques of optical based processing, such as exposure, metrology, inspection, etc., it is important to ensure a precise angular location of a system optical axis relative to a surface of a measured substrate in any measurement point (local or global tilt) regardless of the above angle itself that can be either oblique or normal. Since substrates like a thin semiconductor wafer is usually not flat, precise vacuum chucks are applied in order to hold and move such wafer during measurements as well as to satisfy the flatness condition of this wafer, thus ensuring needed predetermined angle relative to the system optical axis in every measurement point over the wafer. There are different designs of such vacuum chucks that provide high flatness and stability of the wafer under measurements, e.g. U.S. Pat. Nos. 5,534,073, 6,446,948, 6,164,633, 6,265,334. A significant drawback of all such vacuum chucks is that due to a forced contact between the chuck and the wafer, scratches and particles can be generated on the back side of wafer. Number of particles could be reduced by using special plastic materials and precise soft surface treatment, however this significantly increases chuck cost. Another drawback of vacuum chucks is a local tilt appearing between vacuum nozzles.

There is another technique of wafer chucking based on air bearing being offered by CoreFlow Scientific Solutions Ltd. located in Yoqneam, Israel, which enables a good flatness for a wafer without physically contacting with its back side. This technique is even more expensive than vacuum chucking that limits its use in low cost equipment.

One more known technique is called edge-gripping. Many edge-gripping mechanisms are known in the art e.g. U.S. Pat. Nos. 7,032,287, 6,343,905, 6,485,253. Their main functionality is to handle the wafer in such a way that avoids its backside contact with any potential particle generating surfaces. However such edge grip contact does not ensure flatness of the wafer needed for proper optical measurements.

In accordance with one general aspect of the invention is to provide an apparatus of moderate cost and method of wafer holding in an optical metrology tool that enable accurate angular alignment of measured substrate relative to the optical axis of applied optical measurement system in every measurement point over the substrate, without contacting its backside.

This invention combines use of edge contact (edge-grip) with a leveling mechanism and a tilt detector associated with the applied optical measurement system.

### BRIEF DESCRIPTION OF DRAWINGS

The present invention will be understood and appreciated more fully from the following detailed description taken in conjunction with the appended drawings in which:

FIG. 1—general isometric view of the handling, alignment and movement mechanism

FIG. 2—wafer leveling process based on signal from “position sensitive detector” (PSD) or tilt detector device

FIG. 3—Possible displacements for gripping fingers

FIG. 4—optical scheme of a microscope based spectral reflectometer with AF detector

FIG. 5—spectral reflectometer with incorporated tilt detector

FIG. 6—schematic view of a separate tilt detector

FIG. 7—sequence of wafer alignment and measurement

### DETAILED DESCRIPTION

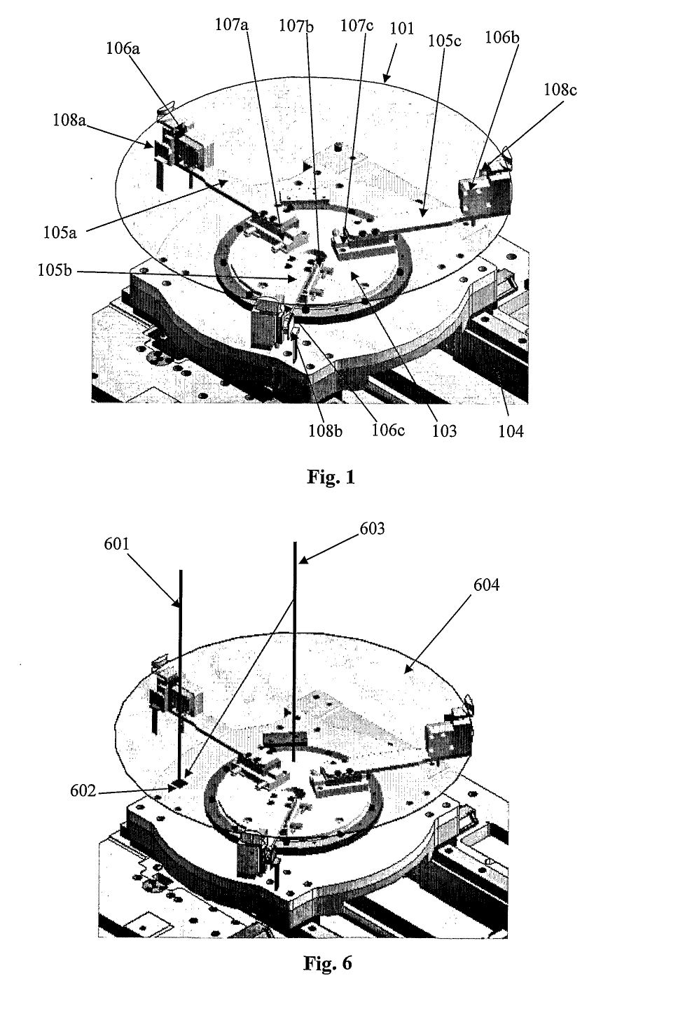

FIG. 1 depicts a general view a wafer stage for holding and leveling the wafer during optical measurements that includes the holding and leveling mechanism according to the present invention. This stage may include several axes for substrate movement during measurements, e.g. rotation, translation (linear movement), enabling R,Θ-movement. Alternatively it may also include additional linear translation enabling so called x,y,—movement in predetermined range, e.g. substantially limited by wafer radius. Additionally it may include focusing axis (precise vertical movement). Substrate 101 (here a silicon wafer used for manufacturing very large scale integrated circuits—VLSI) is brought by an external robot (not shown) onto fingers 102a, 102b and 102c associated with a stage 104.

Substrate clamping is performed by radial translation of the above fingers towards the wafer center 101 which is performed by moving at least one of arms 105a, 105b and 105c. As illustrated in FIG. 1, three linear actuators 107a, 107b and 107c are used for linear moving of arms 105a, 105b and 105c along with forgers 102a, 102b and 102c. Miniature actuators are of either pneumatic or electrical type, e.g. with a travel of about +/−1-5 mm, for example APT-SD6-5 commercially available from Koganei, Japan. Accurate radial movement of the actuators is performed until touching all of the fingers 102 the substrate edge enabling simultaneously both clamping the substrate and its centering relative to the pre-defined vertical axis, which is in the current embodiment the axis of rotation of rotating stage 103. Being clamped and held within the fingers wafer can be moved along all axes of the stage with needed velocity and acceleration. Only edge contact of the wafer with the fingers enables avoiding particles generation on its both front and back sides during wafer handling.

It should be noted that instead of three moving fingers only one or two fingers might be movable while the other finger/s is stationary.

The substrate's surface is usually not flat due to several reasons: a bow due to gravity, an additional bow due to a stress generated in the wafer by fingers and due to wafer curvature generated during wafer processing when different deposited layers cause significant stress (usually non-uniform over the wafer) in the silicon substrate. In order to align the wafer surface for optical measurements there are miniature vertical actuators 106a, 106b and 106c, which support fingers 102a, 102b and 102c, respectively, and are mounted on respective arms. These actuators may be of piezoelectric type, e.g. ST Motor commercially available from Nanomotion Ltd. Yoqneam, Israel enabling high movement resolution in required travel range. In order to ensure needed movement accuracy each actuator is accompanied by a line encoder (108a, 108b and 108c in FIG. 1b) mounted on the same arm. Usually, the resolution needed for optical alignment is lower than one needed for focusing, so low cost actuators and encoders can be used; however in this case a dedicated precise vertical movement additionally is needed for accurate focusing. Alternatively, if high-resolution actuators and encoders are applied, focusing can be reached by equal vertical movement of all three actuators; in this case additional focusing axis is not needed. All the actuators and encoders as well as other moving parts and sensors are connected to a control unit (not shown), which controls all movements by help of appropriate software.

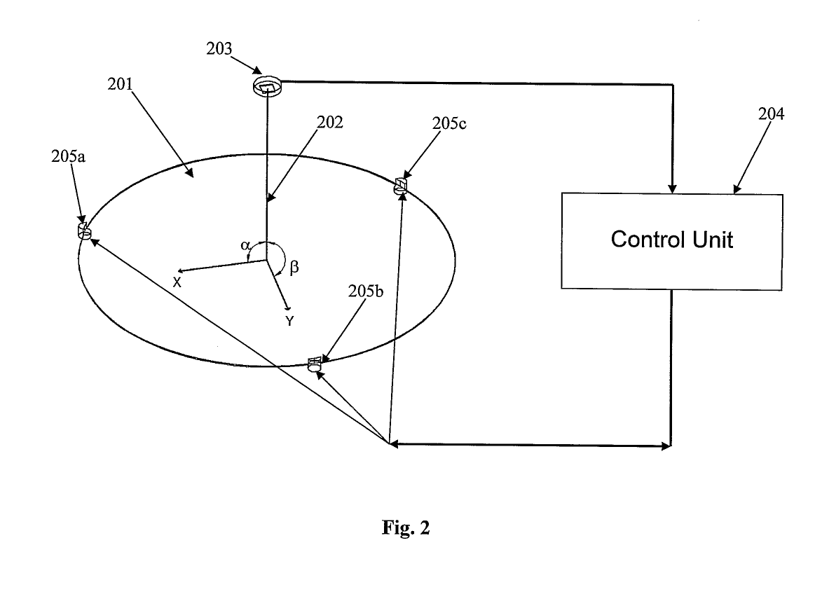

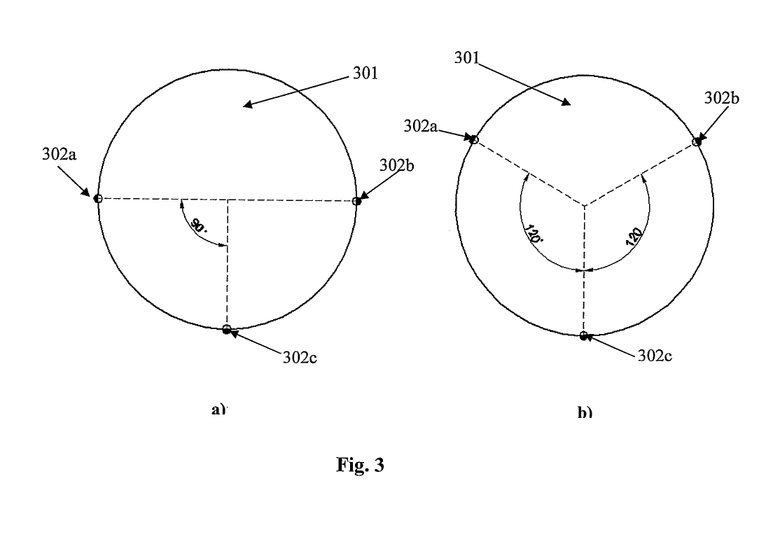

With respect to FIG. 2, in order to perform accurate alignment of the wafer surface (201) in a measurement point relative to the optical axis (202) of the optical measurement system the control unit (204) should receive a feedback from the optical measurement system whether such alignment is in pre-defined tolerance and if not, how much is the mis-alignment. For this purpose the optical measurement system includes a tilt detector (203), which should provide a value of tilt in at least two orthogonal planes crossing the optical axis. Such detector may be an exisiting part of this optical measurement system or as an additional part dedicated for tilt detection. Vertical movement of each finger (205a, 205b, 205c respectively) is calculated by the control unit by help of an algorithm that takes into account location of the measurement point relative to coordinates of the actuators and needed angular correction in this point. In FIG. 3 two different options for the gripping fingers (302a, 302b, 302c) distribution around the wafer (301) are presented. The first option presented in FIG. 3a (orthogonal location of the fingers) has the advantage that the algorithm employed for the wafer surface alignment can be simpler (no coupling between two spacial angles), while the solution in FIG. 3b (symmetric locations of the finger) can offer better mounting stability.

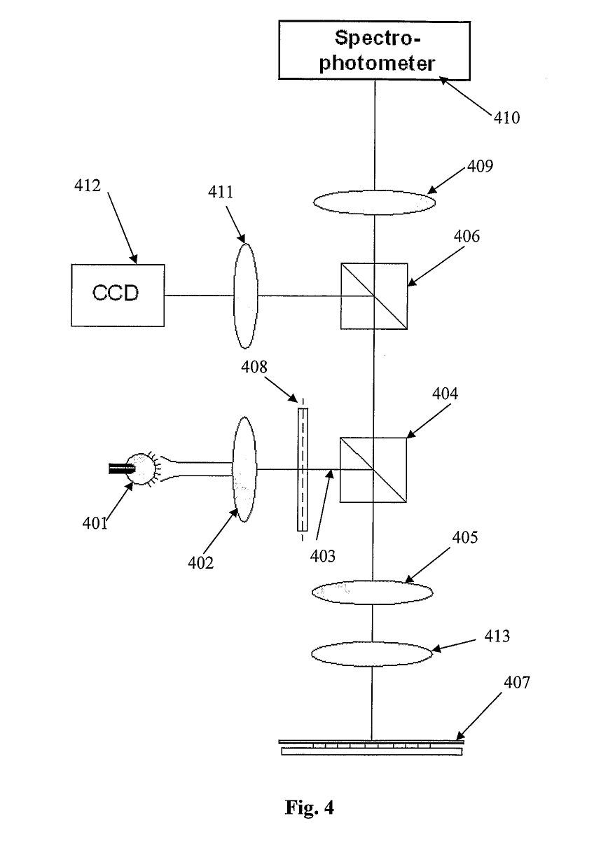

As an example, an optical measurement system of a spectral reflectometer is presented, which is widely used in semiconductor industry for measuring thickness of thin films. However, the same concept is applicable to other optical measuring instruments, like: ellipsometer, scatterometer, etc. Possible configurations of such instruments are illustrateded, e.g. in U.S. Pat. Nos. 5,604,344; 6,045,433; 6,100,985, all assigned to Nova Measuring Instruments. FIG. 4 further exemplifies microscope based optical scheme with built-in autofocusing mechanism, using a detector for measuring defocus of measured wafer by illuminating wafer with a contrast pattern and image processing of the reflected image of this pattern. The light beam 403 from source light 401 passes through condenser 402, contrast pattern 408 and is directed via beam splitter 404 into the main optical path of the imaging system consisting of tube lens 405 and objective 413. The light reflected (or diffracted) from the wafer's 407 surface, which includes also the image of the pattern 408 on the wafer surface, passes through objective 413, tube lens 405, beam splitter 404 and is separated by beam splitter 406, which is preferably but not necessarily a pin-hole mirror, to both a spectrometer arrangement including spectrophotometer 410 and relay lens 409, and a camera arrangement including the imaging device (e.g. CCD) 412 and camera lens 411. Wafer surface is imaged by the objective and tube lens onto beam beam separator 406 and then re-imaged onto the imaging device by the camera lens. The pattern image received by the imaging device 412 is analyzed by a pattern analyzer (not shown) in order to determine the extent of sharpness and to indicate how to change the distance between the wafer 407 and the objective 413 in order to locate the wafer surface exactly in the focual plane of the objective. There are different ways of separating the image of pattern 408 from the image of the wafer pattern. It may be spatial filtration, spectral filtration, bluring the wafer image by moving the wafer during imaging, etc.

The same concept could be used as an angular detector by measuring a defocus separately in different corners of the field of view of the imaging device. Knowing defocus in four points it is easy to calculate a tilt in both said planes.

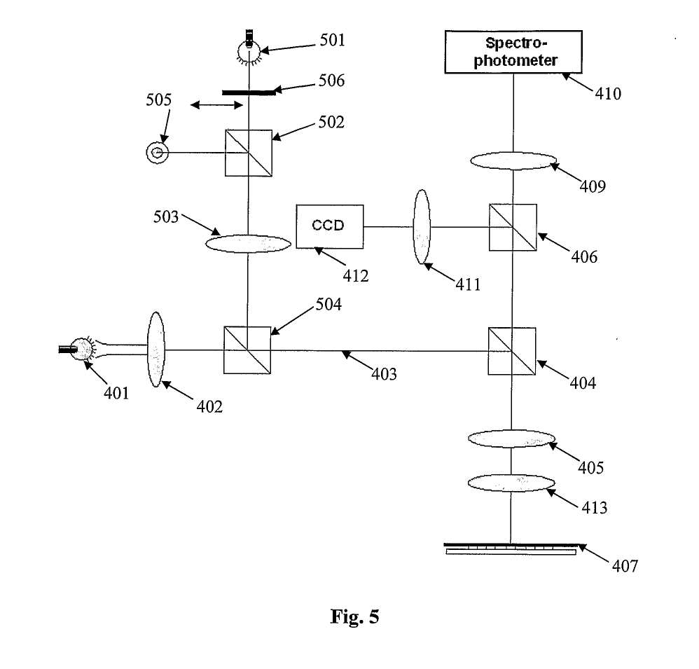

Another solution is illustrated in FIG. 5 where a dedicated tilt detector is incorporated in the illumination path of the existing optical scheme of the spectral reflectometer shown in Fig.4 by help of an additional beam splitter 504. Light probe beam from a light source 501 propagates through a beam splitter 502 and lens 503 and being reflected by a beam splitter 504 is combined with an illumination path of the reflectometer. Being reflected by the measured wafer, this light probe beam partially returns to the illumination path. Beam splitters 504 and 502 and lens 503 directs part of this probe beam toward a sensor 505. Focus of lens 503 is located in a conjugate plane of the wafer so any angular deviation of the reflected probe beam (due to the wafer tilt in the measurement point) from the main optical axis of the reflectometer will cause a lateral shift of the probe beam impinging sensor 505. Light source 501 is preferably a gas laser or laser diode but may be also a LED or a lamp. Sensor 505 may be a PSD (position sensitive detector, e.g. ES1881 from Hamamatsu), quadrant detector, CCD or MOS area array, etc. A shutter 506 is provided in order to cut the light emitted by the light source 501 when this is not needed, e.g. during the wafer measurement by the spectrophotometer. The auto-focusing channel with modified pattern 408 and appropriate image processing utility also could be used as local tilt detector. In that case difference in focus condition in opposite parts of the pattern image along two mutually perpendicular directions due to local tilt should be analyzed additionally.

Yet another option to measure the tilt is by using a separate substantially normal-incidence optical channel (not shown in details), an optical axis thereof 601 is shown in FIG. 6. This optical axis is pre-aligned relative to the main optical axis 603 of the optical measurement system. Such alignment could be carried out for example by help of a dedicated internal target 602 (located on a wafer stage or other precise aligned surface and including a contrast and accurate alignment mark), on which both channels may be placed each after other with a high position accuracy. Accurately measured displacement between two axes should be stored in a memory of the control unit.

During measuring wafer 604 at each measurement point first the separate tilt detector is positioned to the coordinates of this measurement point taking into account the stored displacement between measurement and alignment channels, tilt is calculated and wafer is aligned by help of the actuators so that when the measurement channel is positioned to the same measurement point its optical axis should be well aligned relative to the wafer surface. As known in the art Yet another option to measure the tilt and/or focus conditions is by using a separate—non-normal incidence optical channel (not shown in details), Such systems are known in the art, and illustrated e.g. in U.S. Pat. Nos. 4,558,949; 5,101,226, etc. In that case no additional movement of the substrate is needed, since focus conditions and/or tilt measurement could be performed on the site to be measured by microscope based optical system.

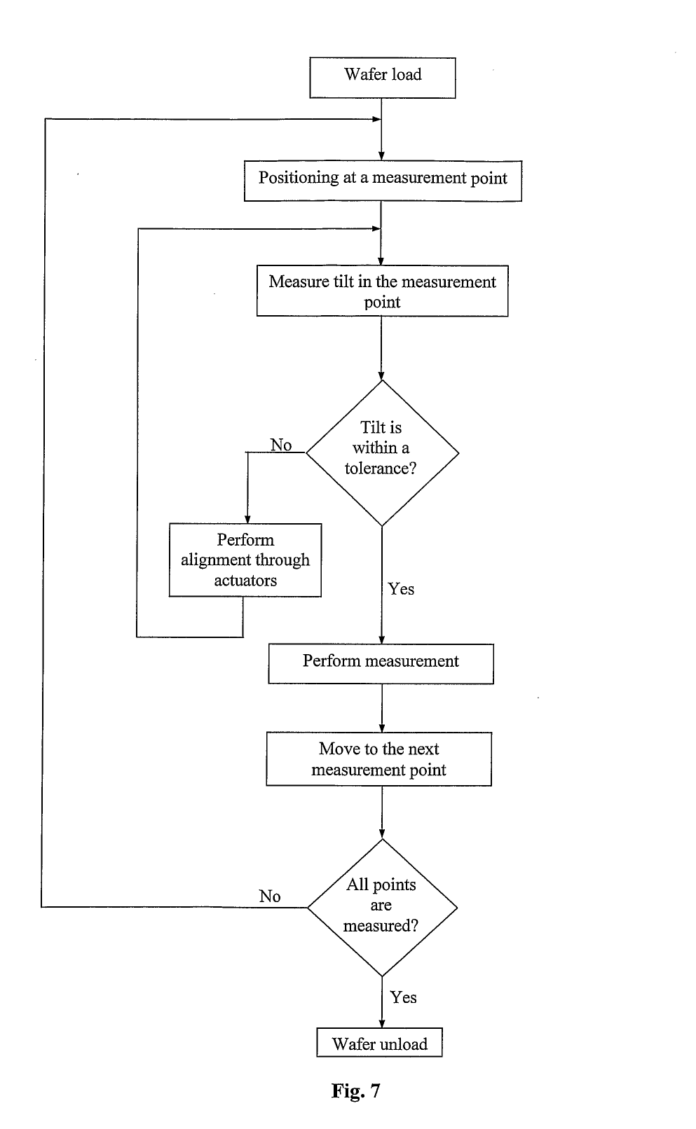

FIG. 7 presents generally a sequence of the tilt alignment and measurement. After loading a wafer (and optional pre-alignment) the wafer is clamp on the wafer stage and moved so that the optical axis of the optical measurement system will reach the pre-defined coordinates of the first measurement point. After accurate positioning, e.g. by help of pattern recognition and auto-focusing, the tilt detector measures the tilt in this point and transfers this data to the control unit. The control unit compares this tilt to the pre-defined tolerance: if it is over the tolerance, it commands the actuators to incline the wafer in such a way that the tilt will be within the tolerance; if the tilt is within the tolerance the control unit commands the optical measurement system to perform measurement at this measurement point. Such procedure repeats for each measurement point until all points are measured after which the wafer is unloaded from the wafer stage.

In the case of the solution with a separate channel for tilt measurement the sequence is slightly different. The stage “positioning at a measurement point” relates to the alignment channel and the stage “measure tilt in the measurement point” includes also an additional movement of the stage in order to position the optical axis of the optical measurement system at the measurement point.

It should be noted that the present invention is also applicable to processing or/and measurement instruments in which optical measurement system is movable while the wafer is stationary.

It also should be noted that after the tilt alignment it might be needed to perform a refocusing because during alignment the wafer surface changes its vertical position. For re-focusing either the same actuators could be moved on the same value in vertical direction or a dedicated vertical axis is used for vertical displacement of the whole chuck with actuators.

A number of embodiments have been described. Nevertheless, it will be understood that various modifications may be made without departing from the spirit and scope of the disclosure. Accordingly, other embodiments are within the scope of the following claims.

1. A system for substrate handling comprising:
an optical tilt detector; a rotatable stage; at least three arms coupled to said rotatable stage each having vertically extended movable along vertical axis fingers to contact the edge of a substrate,
wherein at least one of said arms movably coupled to said stage and a linear actuator coupled to said moveable arm and each of said fingers provided by z-axis miniature linear actuator; and
a control unit connected to said tilt detector and said z-axis linear actuators.

2. The system of claim 1, wherein said Z-axis actuators are of piezoelectric type.

3. The system of claim 1, wherein said tilt detector provides a value of tilt in at least two orthogonal planes.

4. The system of claim 3, wherein said control unit enables running an algorithm that takes into account location of the tilt detector measurement point relative to coordinates of said fingers and needed angular correction in this point.

5. The system of claim 1, wherein said fingers are located on mutually perpendicular axis along substrate surface plane.

6. The system of claim 1, wherein said fingers are distributed symmetrically along substrate surface plane.

7. The system of claim 1 wherein said substrate is a semiconductor wafer.

8. The system of claim 1, wherein said optical tilt detector comprising substantially normal incidence scheme.

9. The system of claim 1, wherein said optical tilt detector comprising substantially oblique incidence scheme.

10. A system for substrate handling for use with optical measurement system comprising:
an optical tilt detector; a rotatable stage; at least three arms coupled to said rotatable stage each having vertically extended movable along vertical axis fingers to contact the edge of a substrate,
wherein at least one of said arms movably coupled to said stage and a linear actuator coupled to said moveable arm and each of said fingers provided by z-axis miniature linear actuator; and
a control unit connected to said tilt detector and said z-axis linear actuators.

11. The system of claim 7, wherein said Z-axis actuators are of piezoelectric type.

12. The system of claim 7, wherein said tilt detector provides a value of tilt in at least two orthogonal planes.

13. The system of claim 7 wherein said optical tilt detector capable perform tilt detection substantially within the measurement site defined by said optical measurement system.

14. The system of claim 12, wherein said optical measurement system comprising an imaging based autofocusing unit capable performing tilt detecting.

15. The system of claim 7, wherein said control unit enables running an algorithm that takes into account location of the tilt detector measurement point relative to coordinates of said fingers and needed angular correction in this point.

16. The system of claim 7, wherein said fingers are located on mutually perpendicular axis along substrate surface plane.

17. The system of claim 7, wherein said fingers are distributed symmetrically along substrate surface plane.

18. The system of claim 7, wherein said optical tilt detector comprising substantially normal incidence scheme.

19. The system of claim 7, wherein said optical tilt detector comprising substantially oblique incidence scheme.

20. The system of claim 7 wherein said substrate is a semiconductor wafer.
